(19) United States
(12) Patent Application Publication
(10) Pub. No.: US 2012/0250292 A1
(43) Pub. Date: Oct. 4, 2012

(54) DISPLAY PANEL UNIT, DISPLAY PANEL MODULE AND DISPLAY DEVICE

(76) Inventors: Atsushi Michimori, Tokyo (JP); Eiji Niikura, Tokyo (JP); Hiroo Sakamoto, Tokyo (JP); Daisuke Katagiri, Tokyo (JP); Tomoyuki Hayashi, Tokyo (JP); Yoshiki Nagaoka, Tokyo (JP)

(21) Appl. No.: 13/516,497

(22) PCT Filed: Dec. 16, 2010
(86) PCT No.: PCT/JP2010/007302

§ 371 Date: Jun. 15, 2012

(30) Foreign Application Priority Data
Dec. 17, 2009 (JP) 2009-286454

(51) Int. Cl. H05K 7/14; G09F 13/04

(52) U.S. Cl. 362/97.1; 361/749

(57) ABSTRACT

A display panel unit 150 includes a display panel 20, a circuit board 40, a flexible board 50 and a housing 60. The display panel 20 has a terminal at a peripheral portion thereof for supply of image signal and displays an image. The circuit board 40 is disposed along a side of the display panel 20, the side having the terminal. The flexible board 50 connects the terminal of the display panel 20 and the circuit board 40 and transmits image signal from the circuit board 40 to the display panel 20. The housing 60 holds the circuit board 40 and the display panel 20. The display panel 20 is fixed to the housing 60 at a center portion of the side along which the circuit board 40 is disposed.

### TECHNICAL FIELD

The present invention relates to a display panel unit, and relates to a display panel module and a display device having the display panel unit.

### BACKGROUND ART

A liquid crystal panel of a liquid crystal display device is held by being sandwiched by a frame-shaped frame made of plastic disposed on a back surface side of the liquid crystal panel and a border frame disposed on a display surface side of the liquid crystal panel. Elongated relay boards are fixed to a side of the frame-shaped frame. The relay boards are connected to electrodes of the liquid crystal panel using flexible boards (COF: Chip On Film).

However, after the liquid crystal display device is assembled, there are cases where the frame-shaped frame may expand or contract due to change in temperature, and positional displacement may occur between the frame-shaped frame and the liquid crystal panel in a horizontal direction and a vertical direction. Therefore, if an end surface of the liquid crystal panel overlaps with a reference surface of the frame-shaped frame, positional displacement occurs between the relay boards fixed to the frame-shaped frame and the liquid crystal panel. This positional displacement causes an unreasonable force to be applied to the flexible boards, or joint portions thereof, between the frame-shaped frame and the liquid crystal panel. For this reason, there is a possibility that disconnection of wirings of the flexible boards may occur. Further, there is a possibility that detachment may occur at the joint portions.

For this reason, one of corners of the liquid crystal panel is aligned with projecting pieces, i.e., a reference position, of the frame-shaped frame. Then, after the liquid crystal panel is fixed by attaching the border frame to the frame-shaped frame, pressing pieces provided on L-shaped members of the frame-shaped frame press the projecting pieces so as to cause the projecting pieces to be deformed. This causes the projecting pieces to move away from the end surface of the liquid crystal panel. This results in that an influence of expansion and contraction of the frame-shaped frame due to change in temperature is not exerted on the liquid crystal panel. Therefore, the disconnection of wirings of the flexible boards and the detachment at the joint portions can be avoided (for example, Patent Document No. 1).

### PRIOR ART DOCUMENT

### Patent Document

Patent Document No. 1: Japanese Laid-open Patent Publication No. 2009-063647 (paragraphs 0002, 0007, 0026 and FIGS. 2 through 6).
Patent Document No. 2: Japanese Laid-open Patent Publication No. 2008-299112 (paragraphs 0056, 0057 and FIG. 7).
Patent Document No. 3: Japanese Laid-open Patent Publication No. 2004-212514 (paragraphs 0015, 0031 and FIG. 1).

### SUMMARY OF THE INVENTION

### Problems to be Solved by the Invention

However, although no problem arises when the liquid crystal panel is small, it may be unavoidable in some cases that an excessive force is applied to the flexible boards when the liquid crystal panel is large. This is because, if the liquid crystal panel is fixed by being sandwiched by the frame-shaped frame and the border frame without having a reference position, a position on the liquid crystal panel, with respect to which the extraction and contraction occurs due to change in temperature, is not defined.

For example, consideration will be given to a case where the liquid crystal panel of 46-inch has a width of approximately 1050 mm and a height of approximately 600 mm, a linear expansion coefficient of the liquid crystal panel made of glass is 5×10⁻⁶, a linear expansion coefficient of the frame-shaped frame made of plastic is 29×10⁻⁶, and a linear expansion coefficient of the relay board is 13×10⁻⁶. A rise in temperature during use is 45 K, and a dimension in a widthwise direction is 1050 mm. The liquid crystal panel made of glass expands by approximately 0.24 mm, the frame-shaped frame made of plastic expands by approximately 1.37 mm, and the relay board expands by approximately 0.61 mm. In this case, if a position at which the liquid crystal panel is fixed to the frame-shaped frame is an end portion of the liquid crystal panel, positional displacement of approximately 1.13 mm occurs at an opposite end portion of the liquid crystal panel. If the relay boards are fixed to the frame-shaped frame at an end portion opposite to the reference position, positional displacement between the liquid crystal panel and the relay boards is approximately 1.13 mm, and it is understood to be unavoidable that an excessive force is applied to the flexible boards.

The present invention is intended to solve the above described problems. A stress on a flexible board is minimized even when deflections or positional displacement of respective parts occur due to a difference in linear expansion coefficient among components such as a liquid crystal panel, a circuit board and a plastic housing of a liquid crystal panel unit. A purpose is to provide a liquid crystal panel unit and a liquid crystal display device that reduce degradation in quality. In this regard, the circuit board is a relay board. The plastic housing is a frame-shaped frame made of plastic. The flexible board electrically connects the liquid crystal panel and the circuit board.

A configuration in which a display panel and a circuit board are connected by a flexible board is employed in various kinds of flat panel display devices other than the liquid crystal panel such as a plasma panel (Patent Document No. 2) and an organic EL panel (Patent Document No. 3). For this reason, although the following embodiments will be described taking a liquid crystal panel unit as an example, the present invention is also applicable to flat panel units other than the liquid crystal panel unit.

### Means of Solving the Problems

A display panel unit according to the present invention includes a display panel having a terminal at a peripheral portion thereof for supply of image signal, the display panel displaying an image, a circuit board disposed along a side of the display panel, the side having the terminal, a flexible board connecting the terminal of the display panel and the circuit board and transmitting image signal from the circuit board to the display panel, and a housing that holds the circuit board and the display panel, wherein the display panel is fixed to the housing at a center portion of the side along which the circuit board is disposed.

### Effects of the Invention

The display panel unit according to the present invention is capable of achieving advantages of reducing a stress on the flexible board that occurs due to a rise in temperature in the display device, and reducing disconnection of wirings of the flexible board.

### BRIEF DESCRIPTION OF THE DRAWINGS

FIG. 1 is an exploded perspective view showing a configuration of a liquid crystal panel module according to Embodiment 1 of the present invention.

FIG. 2 is a detailed view showing a configuration of a main part of the liquid crystal panel module according to Embodiment 1 of the present invention.

FIG. 3 is a detailed view showing the configuration of the main part of the liquid crystal panel module according to Embodiment 1 of the present invention.

FIG. 4 is a detailed view showing a configuration of a main part of a flexible board according to Embodiment 1 of the present invention.

FIG. 5 is a sectional view showing the configuration of the liquid crystal panel module according to Embodiment 1 of the present invention.

FIG. 6 is a sectional view showing the configuration of the liquid crystal panel module according to Embodiment 1 of the present invention.

FIG. 7 is an exploded perspective view showing a configuration of a liquid crystal device according to Embodiment 1 of the present invention.

FIG. 8 shows sectional views showing a configuration of a main part of a liquid crystal panel module according to Embodiment 2 of the present invention.

FIG. 9 is a plan view showing the configuration of the main part of the liquid crystal panel module according to Embodiment 2 of the present invention.

FIG. 10 is a sectional view showing the configuration of the main part of the liquid crystal panel module according to Embodiment 2 of the present invention.

FIG. 11 is a plan view showing the configuration of the main part of the liquid crystal panel module according to Embodiment 2 of the present invention.

FIG. 12 is a sectional view showing the configuration of the main part of the liquid crystal panel module according to Embodiment 2 of the present invention.

FIG. 13 is a plan view showing the configuration of the main part of the liquid crystal panel module according to Embodiment 2 of the present invention.

FIG. 14 is a sectional view showing the configuration of the main part of the liquid crystal panel module according to Embodiment 2 of the present invention.

### MODE FOR CARRYING OUT THE INVENTION

### Embodiment 1

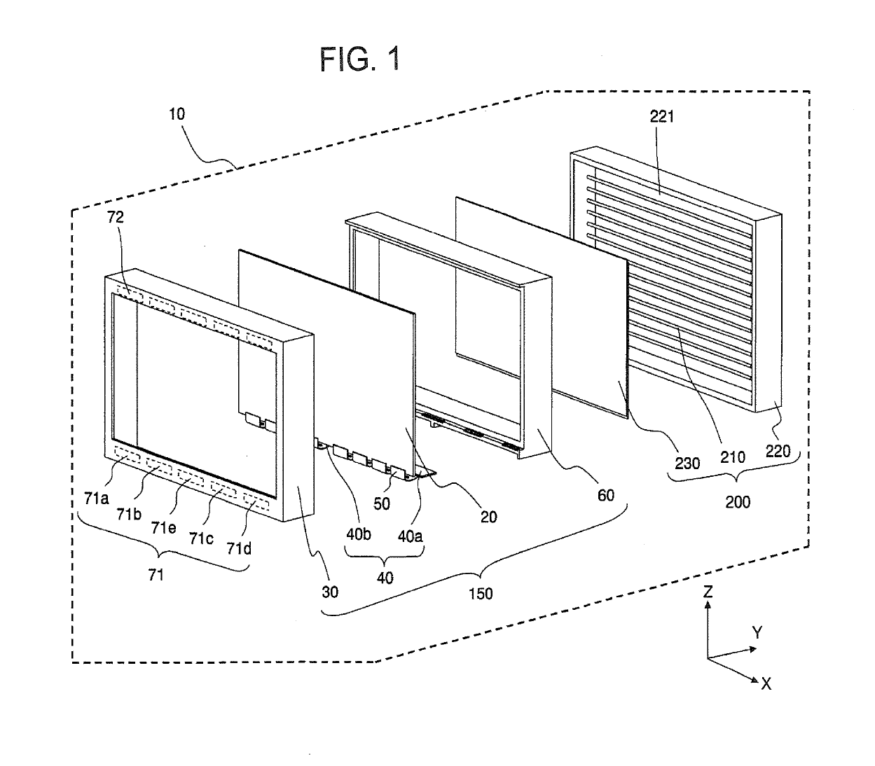

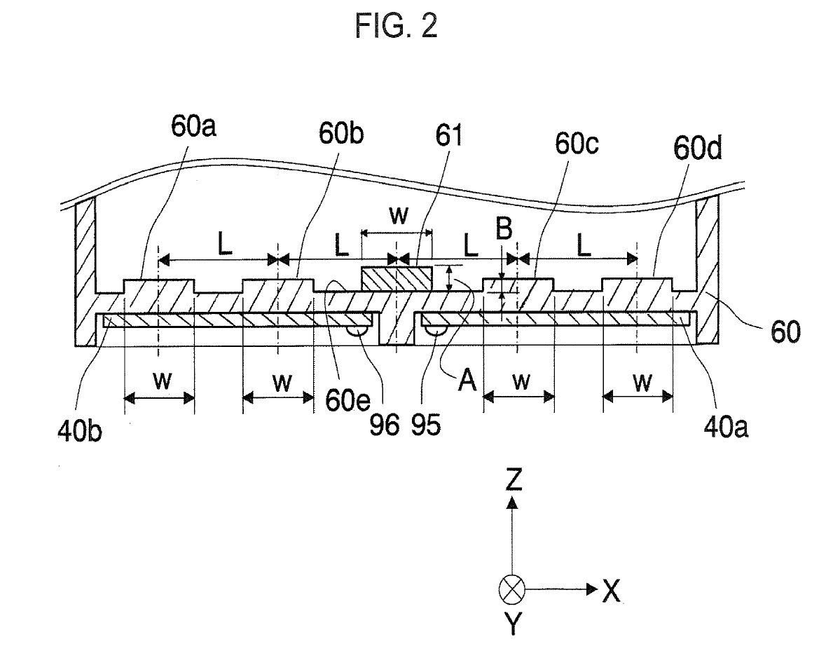

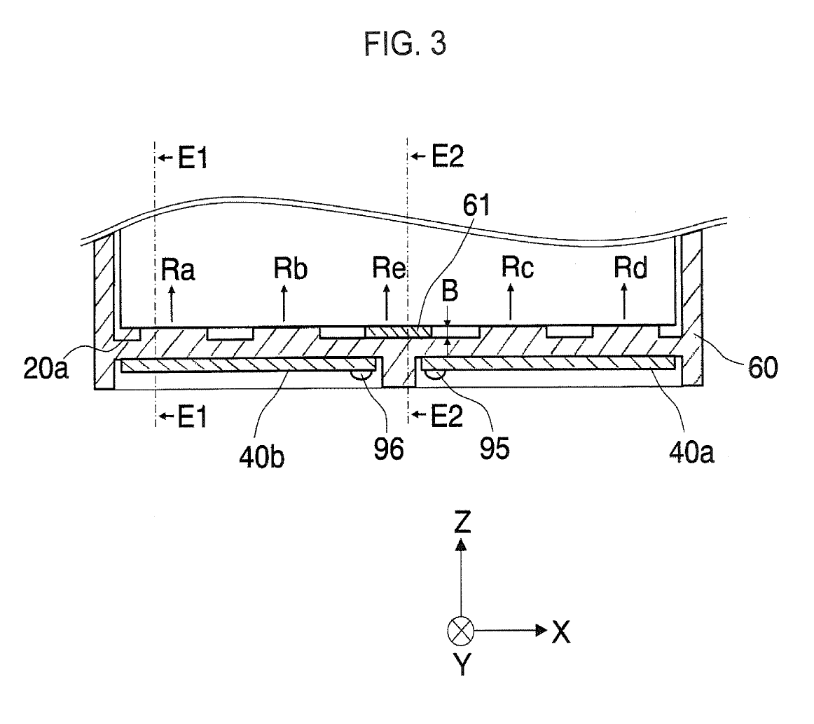

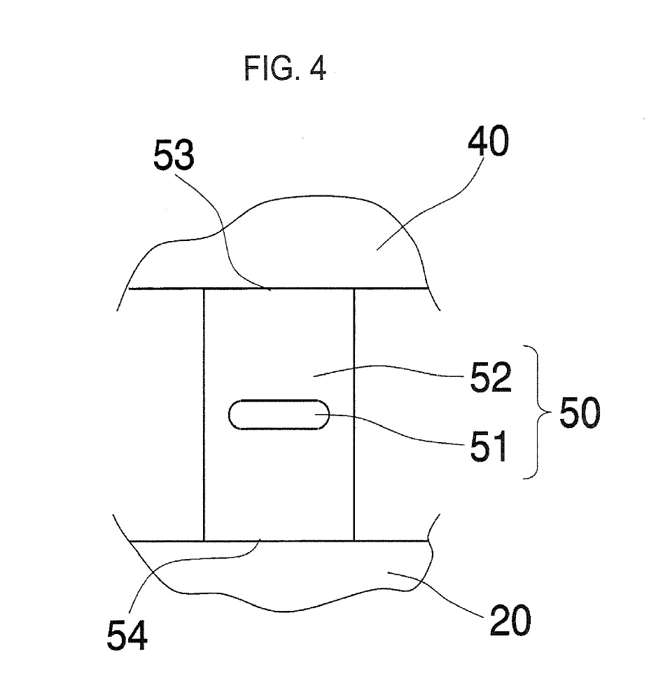

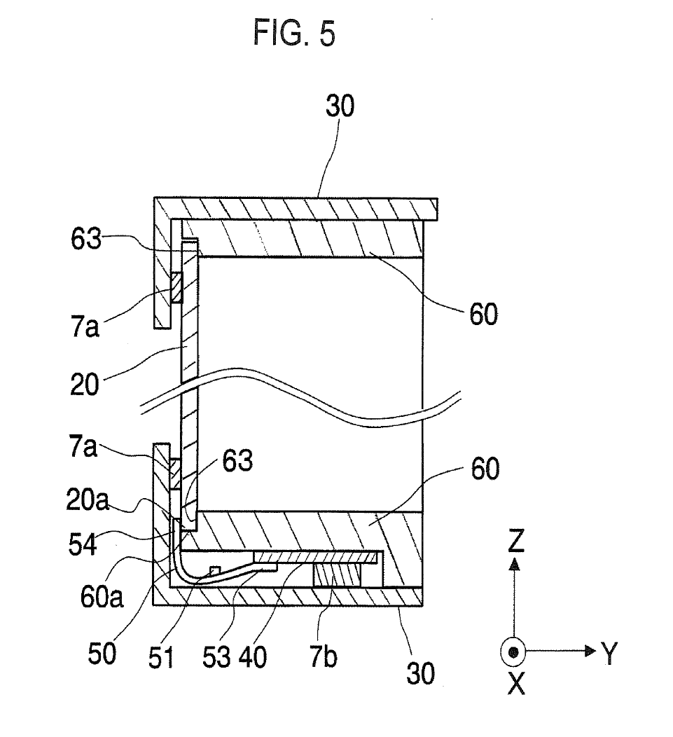

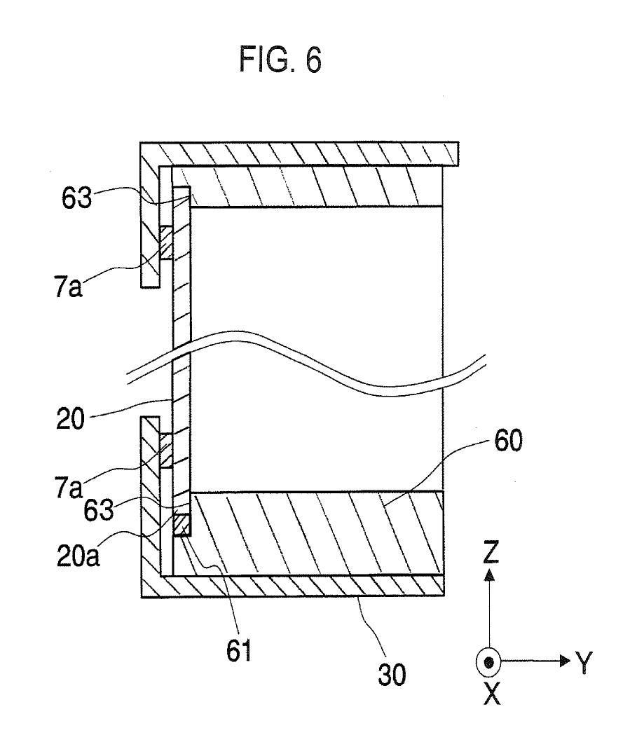

FIG. 1 is an exploded perspective view showing a configuration of a liquid crystal panel module 10 of a liquid crystal display device according to Embodiment 1 of the present invention. FIGS. 2 and 3 are detailed views showing a main part, i.e., a vicinity of a lower end of a liquid crystal panel 20. FIG. 4 is a configuration view showing a configuration of a flexible board 50. FIGS. 5 and 6 are partial sectional views respectively taken along a line E1-E1 and a line E2-E2 in FIG. 3. In the respective figures, an upward direction of the liquid crystal display device is defined as +Z direction, and a downward direction is defined as −Z direction. Along a horizontal direction of the liquid crystal panel module 10, a right direction when seeing a display surface is defined as +X direction, and a left direction is defined as −X direction. Along a depth direction of the liquid crystal panel module 10, a direction from the display surface toward a back surface side is defined as +Y direction, and a direction from the back surface toward the display surface side is defined as −Y direction.

The liquid crystal panel 20 as a display panel has two rectangular glasses elongated in the horizontal direction as the X direction, and a liquid crystal layer (not shown). The liquid crystal layer is disposed between two glasses. As shown in FIG. 4, the flexible board 50 is constituted by an IC chip 51 and a film portion 52. The IC chip 51 is fixed to a surface of the film portion 51 using solder or the like so as to allow current flow. An end portion 54 of the film portion 52 is connected to a terminal portion on a display surface of the liquid crystal panel 20 using a solder, an anisotropic conductive film (ACF) or the like so as to allow current flow. The other end portion 53 is connected to a terminal portion of a circuit board 40 using a solder, an anisotropic conductive film or the like so as to allow current flow.

A backlight unit 200 includes a plurality of lamps 210, a back frame 220 and optical sheets 230. The lamps 210 are light sources. The back frame 220 constitutes a rear housing. The back frame 220 has a box-shape having an open surface 221. The optical sheets 230 include a plurality of optical sheets. These optical sheets are formed of transparent planar material, and have a diffusion effect and a lens effect.

The back frame 220 having the box-shape houses therein the lamps 210 constituted by, for example, cold cathode fluorescent lamps (CCFLs) or the like and arranged at predetermined constant intervals in the Z direction. The optical sheets 230 have elongated rectangular shapes elongated in the horizontal direction, i.e., the X direction as is the case with the liquid crystal panel 20. The optical sheets 230 are laminated on the open surface 221 side, i.e., the −Y direction side of the back frame 220. The optical sheets 230 are held by being sandwiched by the back frame 220 and a chassis 60.

An inner surface of the back frame 220 having the box-shape constitutes a reflection surface. Irradiation light emitted by the lamps 210 in the +Y direction is reflected, and is emitted through the open surface 221 in the −Y direction.

The circuit boards 40 are formed of glass epoxy boards each having an elongated rectangular shape elongated in the X direction. The circuit boards 40 are constituted by two circuit boards 40a and 40b. The two circuit boards 40a and 40b are disposed on a lower side, i.e., the −Z direction side of the liquid crystal panel module 10 as a display panel module. The circuit boards 40a and 40b are disposed so that longer sides thereof are disposed along a side of the liquid crystal panel 20 having terminals. The expression of being “disposed along the side of the liquid crystal panel having the terminals” includes a case where the sides of the circuit boards 40 are disposed along the side of the liquid crystal panel 20. In such a case, the surface of the liquid crystal panel 20 and the surfaces of the circuit boards 40 are disposed on a same plane, or on mutually parallel planes. Further, a case where the surface of the liquid crystal panel 20 and the surfaces of the circuit boards 40 are disposed at a certain angle with respect to each other is also included. Further, the expression of being “disposed along the side of the liquid crystal panel having the terminals” also includes a case where the surfaces of the circuit boards 40 are disposed along the side of the liquid crystal panel 20. This is a case where the display panel 20 and the circuit boards 40 are disposed in a T-shape. In this regard, an angle between the display panel 20 and the circuit board 40 is not limited to right angle.

The circuit boards 40a and 40b are disposed so that shorter sides of the circuit boards 40a and 40b are adjacent to each other. The circuit boards 40a and 40b are fixed to the chassis 60 using screws 95 and 96 at respective ends of the circuit boards 40a and 40b on a center side of the liquid crystal panel 20. Four flexible boards 50 are connected to each of the circuit boards 40a and 40b, which correspond to eight flexible boards 50 in total. In this regard, although the circuit boards 40 are constituted by two boards in this embodiment, it is possible to employ a single board or more than two boards. Further, although eight flexible boards 50 are provided for the circuit boards 40a and 40b, it is also possible to provide the circuit boards in the number according to a screen size and the number of pixels of the liquid crystal panel 20.

In FIG. 2, four receiving surfaces 60a, 60b, 60c and 60d having convex-shapes are formed on the chassis 60. The receiving surfaces 60a, 60b, 60c and 60d are configured to receive a lower end portion 20a of the liquid crystal panel 20. The receiving surfaces 60a, 60b, 60c and 60d are formed so as to having a same width W and a same height B. A resilient member 61, which has the width W and a height A, is bonded to a center portion 60e formed between the receiving surfaces 60b and 60c using a double-faced adhesive tape or the like. For example, a rubber, sponge or the like can be employed as the resilient member 61. The resilient member 61 corresponds to a first resilient member.

A distance between a center of the receiving surface 60a in the X-axis direction and a center of the receiving surface 60b in the X-axis direction is “L”. Similarly, a distance between a center of the receiving surface 60b in the X-axis direction and a center of the resilient member in the X-axis direction also is “L”. A distance between the center of the resilient member 61 in the X-axis direction and a center of the receiving surface 60c in the X-axis direction also is “L”. A distance between the center of the receiving surface 60ca in the X-axis direction and a center of the receiving surface 60d in the X-axis direction also is “L”.

FIG. 3 shows a state where the liquid crystal panel 20 is placed on the receiving surfaces 60a, 60b, 60c and 60d and the resilient member 61. In FIG. 3, the resilient member 61 is compressed from the height A to the height B. For example, when an elastic modulus of the resilient member 61 is K (N/mm), a generated reaction force Re is expressed by the following equation (1).

Re=(A−B)×K[N] (1)

Reaction forces applied to four portions of the lower end portion 20a of the liquid crystal panel 20 contacting the receiving surfaces 60a, 60b, 60c and 60d are respectively expressed by Ra, Rb, Rc and Rd. An equation of equilibrium of forces in the Z direction as the vertical direction can be expressed by the following equation (2). In this regard, it is assumed that a gravity center of the liquid crystal panel 20 coincides with a center position of the liquid crystal panel 20 in the X direction.

M×g=Ra+Rb+Rc+Rd+Re[N] (2)

Further, when a rotation fulcrum O is set to be a center position of the resilient member 61 in the X-axis direction which is considered to be the position of the reaction force Re, equilibrium of moments about the rotation fulcrum O is expressed by the following equation (3).

Ra×2L+Rb×L=Rc×2L+Rd×L[N·mm] (3)

From the equation (3), the following equation (4) is obtained.

(Ra−Rd)×2L+(Rb−Rc)×L=0[N·mm] (4)

Since the reaction forces Ra, Rb, Rc and Rd are symmetrical about the rotation fulcrum O, the following equations (5) and (6) are obtained.

Ra=Rd[N] (5)

Rb=Rc[N] (6)

In this regard, when the chassis 60 expands in the X-axis direction due to rise in temperature, friction forces applied to the liquid crystal panel 20 by the receiving surfaces 60a, 60b, 60c and 60d are expressed by the following equation (7) when a friction coefficient between the receiving surfaces 60a, 60b, 60c and 60d and the liquid crystal panel 20 is expressed by μ₁. These friction forces are external forces applied to the liquid crystal panel 20 in a direction along the lower side.

μ₁×(Ra+Rb−Rc−Rd)=0[N] (7)

For this reason, the receiving surfaces 60a and 60b of the chassis 60 expand in the −X direction, and the receiving surfaces 60c and 60d expand in the +X direction with respect to the center position of the resilient member 61 in the X-axis direction which corresponds to the center position of the liquid crystal panel 20 in the X direction.

However, it is unlikely in practice that the liquid crystal panel 20 is received by all of the receiving surfaces 60a, 60b, 60c and 60d. The liquid crystal panel is usually received by two receiving surfaces among four receiving surfaces, i.e., the receiving surfaces 60a and 60c, the receiving surfaces 60a and 60d, the receiving surfaces 60b and 60c, or the receiving surfaces 60b and 60d. In this regard, when the liquid crystal panel 20 is received by the receiving surfaces 60a and 60b or the receiving surfaces 60c and 60d, the liquid crystal panel 20 is received only by the resilient member 61 in practice according to the equation (3).

Among these receiving surfaces, when the receiving surfaces 60a and 60d or the receiving surfaces 60b and 60c receive the liquid crystal panel 20, the friction forces applied to the liquid crystal panel 20 are balanced in the X direction. Therefore, the receiving surface 60a or 60b of the chassis 60 expands in the −X direction and the receiving surface 60c or 60d expands in the +X direction with respect to the center position of the resilient member 61 in the X-axis direction. Further, the center position of the resilient member 61 in the X-axis direction corresponds to the center position of the liquid crystal panel 20.

However, when the receiving surfaces 60a and 60c receive the liquid crystal panel 20 or when the receiving surfaces 60b and 60d receive the liquid crystal panel 20, the friction forces applied to the liquid crystal panel 20 are not balanced in the X direction. Therefore, unless the friction force applied to the liquid crystal panel 20 by the resilient member 61 is greater than or equal to a predetermined value, the chassis 60 does not expand with respect to the center position of the liquid crystal panel in the X direction. For example, a relationship between friction forces applied to the liquid crystal panel 20 by the chassis 60 when the receiving surfaces 60a and 60c receive the liquid crystal panel 20 is expressed by the following equation (8). In this regard, a friction coefficient between the resilient member 61 and the liquid crystal panel 20 is expressed by μ₀.

μ₁×Ra+μ₀×Re−μ₁×Rc=0[N] (8)

Here, the reaction force Ra is expressed by the following equation (9).

M×g=Ra+Rc+Re

Ra×2L=Rc×L

Ra=(M×g−Re)/3[N] (9)

In this regard, Rc is expressed by the following equation (10).

Rc=2×(M×g−Re)/3[N] (10)

When the equations (9) and (10) are substituted into the equation (8), the following equation (11) is obtained.

μ₁×(Rc−Ra)=μ₁×(M×g−Re)/3[N] (11)

Therefore, when the friction force applied to the liquid crystal panel 20 by the resilient member 61 is greater than μ₁×(Rc−Ra), the chassis 60 expands with respect to the center position of the liquid crystal panel 20 in the X direction. This condition is satisfied by Re expressed by the following equation (12).

μ₀×Re≧μ₁×(Rc−Ra)=μ₁×(M×g−Re)/3

μ₀×Re≧μ₁×(M×g−Re)/3

Re≧μ₁×M×g/(3μ₀+μ₁)[N] (12)

As above, there are cases where uneven friction forces are applied to the liquid crystal panel 20 by the −X direction part and the +X direction part of the chassis 60 with respect to the center portion of the liquid crystal panel 20 in the X direction. However, the friction force applied to the liquid crystal panel 20 by the resilient member 61 is greater than a difference between the friction forces applied to the liquid crystal panel 20 by the −X direction part and the +X direction part of the chassis 60. Therefore, the chassis 60 expands in the X direction with respect to the resilient member 61 at the center of the liquid crystal panel 20 in the X direction.

In this regard, the equation (3) is based on the condition that the gravity center of the liquid crystal panel 20 coincides with the center position of the liquid crystal panel 20 in the X direction. The gravity of the liquid crystal panel 20 is mainly occupied by weights of the two glasses sandwiching the liquid crystal layer. Therefore, even when other components are attached to the liquid crystal panel 20 in an asymmetrical manner, the gravity center is located approximately at the center position of the liquid crystal panel 20. Even when the gravity center of the liquid crystal panel 20 does not coincide with the center position of the liquid crystal panel 20 in the X direction, a distance therebetween is not large. Therefore, when the resilient member 61 is configured to receive the liquid crystal panel 20 at a portion including both of the gravity center of the liquid crystal panel 20 and the center position of the liquid crystal panel 20, it is possible to obtain approximately the same results. A center portion is an area including both of the gravity center of the liquid crystal panel 20 and the center position of the liquid crystal panel 20.

The circuit boards 40a and 40b are fixed to the chassis 60 using screws at positions close to the center position of the liquid crystal panel 20 in the X direction so as not to cause positional displacement between the circuit boards 40a and 40b. Therefore, the circuit boards 40a and 40b expand in the X direction with respect to this screw fixing position. The resilient member 61 is disposed at the center position of the liquid crystal panel 20 in the X direction.

For example, it is assumed that the liquid crystal panel module 10 of 46-inch is used, and the rise in temperature is 45K. The circuit boards 40a and 40b are fixed to the chassis 60 using screws at substantially center position of the liquid crystal panel 20 in the X direction. Therefore, the chassis 60 expands with respect to the center position of the liquid crystal panel 20. It is assumed that a length of each of the circuit boards 40a and 40b is 525 mm which corresponds to a half of 1050 mm, i.e., a size of the liquid crystal panel 20 in the horizontal direction. In this case, each of the circuit boards 40a and 40b expands by approximately 0.31 mm at each end portion of the liquid crystal panel 20 in the X direction. In contrast, the liquid crystal panel 20 expands by approximately 0.12 mm. Therefore, a maximum positional displacement between the liquid crystal panel 20 and the circuit boards 40a and 40b is 0.19 mm.

In this way, the maximum positional displacement between both terminal portions of the flexible board 50 can be reduced to 0.19 mm which is approximately one-sixth of 1.13 mm as considered in the conventional art. Therefore, the positional displacement between the circuit boards 40a and 40b and the liquid crystal panel can be suppressed. Further, disconnection of wirings on the flexible board due to stress can be reduced.

In this regard, in the above described embodiment, a positioning between the liquid crystal panel 20 and the chassis 60 depends on the friction force between the resilient member 61 and the lower end portion 21 of the liquid crystal panel 20. However, for example, it is also possible to affix a double-faced adhesive tape on an upper surface, i.e., a surface of the +Z direction of the resilient member 61, and to fix the resilient member 61 and the liquid crystal panel 20 to each other by bonding. This enables a surer positioning. However, this method has a disadvantage in that operability in detachment of the liquid crystal panel 20 or the like is reduced.

Further, when the liquid crystal panel 20 is attached to the chassis 60, it is necessary to position the liquid crystal panel 20 and the chassis 60 to each other in the X direction. Assembly can be performed using a tool for positioning the liquid crystal panel 20 with respect to the chassis 60.

Here, consideration will be given to a case where the circuit boards 40a and 40b are not fixed to the chassis 60 at the position in the vicinity of the center position of the liquid crystal panel 20 in the X direction, but are fixed to the chassis 60 at positions in the vicinities of both ends of the liquid crystal panel 20 in the X direction using screws. In this case, positions of both ends of the circuit boards 40a and 40b in the X direction change according to a linear expansion coefficient of the chassis made of plastic. The linear expansion coefficient of the chassis 60 is 29×10⁻⁶, and the linear expansion coefficient of each of the circuit boards 40a and 40b is 13×10⁻⁶ as described above. The chassis 60 corresponds to a housing as a frame-shaped frame made of plastic. The circuit boards 40a and 40b correspond to relay boards.

It is assumed that the length of each of the circuit boards 40a and 40b is 525 mm which corresponds to a half of approximately 1050 mm, i.e., a width of the liquid crystal panel 20. The rise in temperature is 45 K. In this case, when the circuit boards 40a and 40b are fixed to both ends of the chassis 60 in the X direction using screws, a maximum moving amount of each of the circuit boards 40a and 40b is 525 mm×29×10⁻⁶×45=0.69 mm. This is approximately 2.2 times as large as approximately 0.31 mm when the circuit boards 40a and 40b are fixed to the position in the vicinity of the center position of the liquid crystal panel 20 in the X direction using screws.

This shows that the positional displacement between the circuit boards 40a and 40b and the liquid crystal panel 20 is suppressed by fixing the circuit boards 40a and 40b at the position in the vicinity of the center position of the liquid crystal panel 20 in the X direction using screws. Further, it is understood that it is important to fix the circuit boards 40a and 40b at the position in the vicinity of the center position of the liquid crystal panel 20 in the X direction using screws, in terms of reducing disconnection of wirings of the flexible board due to stress.

Next, description will be made with reference to FIGS. 5 and 6. FIG. 5 is a sectional view taken along the line E1-E1 in FIG. 3. The lower end portion 20a of the liquid crystal panel 20 is received by the receiving surface 60a of the chassis 60. The end portion 54 of each flexible board 50 is connected to the terminal disposed on the lower end of the liquid crystal panel 20 so as to allow current flow. In contrast, the end portion 53 of the flexible board 50 is connected to the terminal of the circuit board 40 so as to allow current flow. The film portion 52 of the flexible board 50 extends in the −Z direction, i.e., in substantially vertical direction from the end portion 54, is bent substantially at 90 degrees toward the +Y direction, and extends in the +Y direction. The end portion 53 is connected to the circuit board 40.

The circuit boards 40 are fixed to the chassis 60 using the screws 96 at the end portions on the center side of the liquid crystal panel 20. However, on either end side of the liquid crystal panel 20, an upper surface of the circuit board 40 is pressed against a lower surface of the chassis 60 using a cushion 7b as a resilient member. Therefore, even when a positional displacement between the chassis 60 and the circuit board 40 occurs due to change in temperature, the chassis 60 and the circuit board 40 can mutually expand or contract in the X direction. The lower surface corresponds to a surface facing the −Z direction. The upper surface corresponds to a surface facing the +Z direction.

FIG. 6 is a sectional view taken along the line E2-E2 in FIG. 3. The lower end portion 20a of the liquid crystal panel 20 is received by the resilient member 61. In contrast, cushions 7a are provided on a display surface side of the liquid crystal panel 20 and between the liquid crystal panel 20 and a frame 30. The display surface side corresponds to the −Y direction side of the liquid crystal panel 20. The frame 30 is a frame body. The liquid crystal panel 20 is held by being sandwiched by the frame 30 and the chassis 60 via the cushions 7a. Therefore, even when positional displacement occurs among the frame 30, the chassis 60 and the liquid crystal panel 20, the frame 30, the chassis 60 and the liquid crystal panel 20 can respectively expand or contact in the X direction.

In this regard, a friction coefficient μ₂ between the cushion 7a and the liquid crystal panel 20 and a friction coefficient μ₃ between the back surface of the liquid crystal panel 20 and a receiving surface 63 of the chassis 60 are very small as compared with the friction coefficients μ₀ and μ₁. In other words, the friction coefficients μ₂ and μ₃ have little effect on the above described equations (7) and (8). If the friction coefficient μ₂ has an effect on the above described equations (7) and (8), it is necessary to determine a difference between a sum of friction forces applied to the liquid crystal panel 20 by the +X direction part of the cushion 7a with respect to the resilient member 61 and a sum of friction forces applied to the liquid crystal panel 20 by the −X direction part of the cushion 7a with respect to the resilient member 61, and it is necessary to add the difference to a right-hand side of the equation (12).

Next, description will be made of a provision of the flexible boards 50 on the lower side of the liquid crystal panel 20. The lower side corresponds to the −Z direction side. For example, consideration will be given to a case where the flexible boards 50 are disposed on the upper side of the liquid crystal panel 20. The upper side corresponds to the +Z direction side. When the temperature of the liquid crystal panel module 10 rises, the liquid crystal panel 20 and the chassis 60 expand with respect to the receiving surfaces 60a, 60b, 60c and 60d of the chassis 60.

For example, if the liquid crystal panel of 46-inch has a height of 600 mm, a positional displacement amount at the upper end of the liquid crystal panel 20 in the +Z direction is 600 mm×5×10⁻⁶×45=0.14 mm. For the chassis 60 made of plastic to which the circuit boards 40a and 40b are fixed, a positional displacement amount is 600 mm×29×10⁻⁶×45=0.78 mm. A difference between the positional displacement amounts is approximately 0.65 mm which is very large. Therefore, the position of the end portion 53 of the flexible board 50 on the circuit boards 40a and 40b side expands by approximately 0.65 mm in the Z direction with respect to the position of the end portion 54 on the liquid crystal panel 20 side.

By comparison, consideration will be given to a case where the flexible boards 50 are provided on the lower side of the liquid crystal panel 20 as shown in FIG. 1. The lower side corresponds to the −Z direction side. The lower end portion 20a, i.e., an end portion of the liquid crystal panel 20 in the −Z direction is positioned by the receiving surfaces 60a, 60b, 60c and 60d on the lower end portion of the chassis 60. The position of the end portion 53 of the flexible board 50 does not substantially change with respect to the position of the end portion 54 of the flexible board 50. The end portion 54 is the end portion of the flexible board 50 connected to the lower end portion of the liquid crystal panel module 10. The end portion 53 is the end portion of the flexible board 50 connected to the circuit boards 40a and 40b fixed to the lower end portion of the chassis 60.

For this reason, the circuit boards 40a and 40b are fixed to the lower side of the chassis 60. The lower side corresponds to the −Z direction side. Further, the terminals provided on the lower end portion 20a of the liquid crystal panel 20 are connected to the terminals provided on the circuit boards 40a and 40b using the flexible boards 50. This enables suppression of positional displacement of the end portion 54 of each flexible board 50 with respect to the other end portion 53 due to change in temperature of the liquid crystal panel module 10. In other words, the positional displacement between the circuit boards 40a and 40b and the liquid crystal panel can be suppressed. Further, disconnection of wirings of the flexible board due to stress can be reduced.

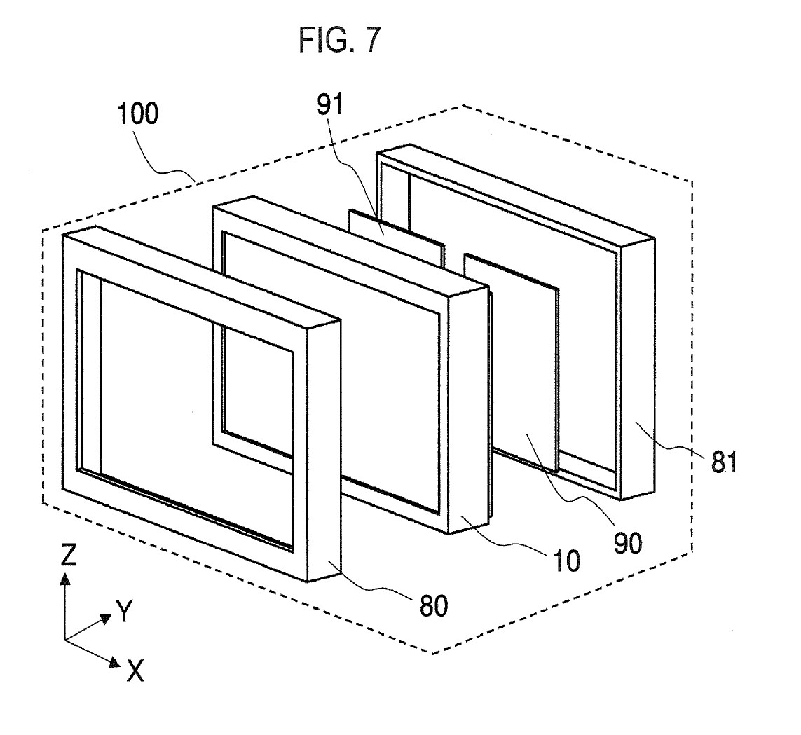

FIG. 7 is an exploded perspective view showing a liquid crystal display device 100 to which the liquid crystal panel module 10 according to Embodiment 1 is mounted. The liquid crystal panel module 10, a signal processing board 90 and a power source board 91 are held in a front housing 80 having a frame-shape surrounding a screen and a rear housing 81. The liquid crystal display device 100 includes the front housing 80, the liquid crystal panel module 10, the signal processing board 90, the power source board 91 and the rear housing 81. The liquid crystal panel module 10, the signal processing board 90 and the power source board 91 are electrically connected to each other using cables, connectors and the like.

The signal processing board 90 is a board that performs signal processing for causing the liquid crystal panel module 20 to display image signal obtained from outside. The signal processing board 90 also has a not-shown tuner for receiving television image signal, a connector for inputting external signal, and the like. The power source board 90 is a board for supplying power source to the liquid crystal panel module 20, the lamps 210 and the signal processing board 90 and the like. The lamps 210 are the light sources constituted by the above described CCFL or the like mounted in the backlight unit 200.

### Embodiment 2

In Embodiment 1, the lower end portion 20a of the liquid crystal panel 20 is received by the receiving surfaces 60a, 60b, 60c and 60d provided on the lower end portion of the chassis 60 and the resilient member 61 provided at the center portion in the X direction. In Embodiment 2, cushions 71 provided on the upper end portion and the lower end portion of the liquid crystal panel 20 press the liquid crystal panel 20 in the −Y direction. The cushions 71 correspond to second resilient members. The −Y direction is a direction perpendicular to the display surface.

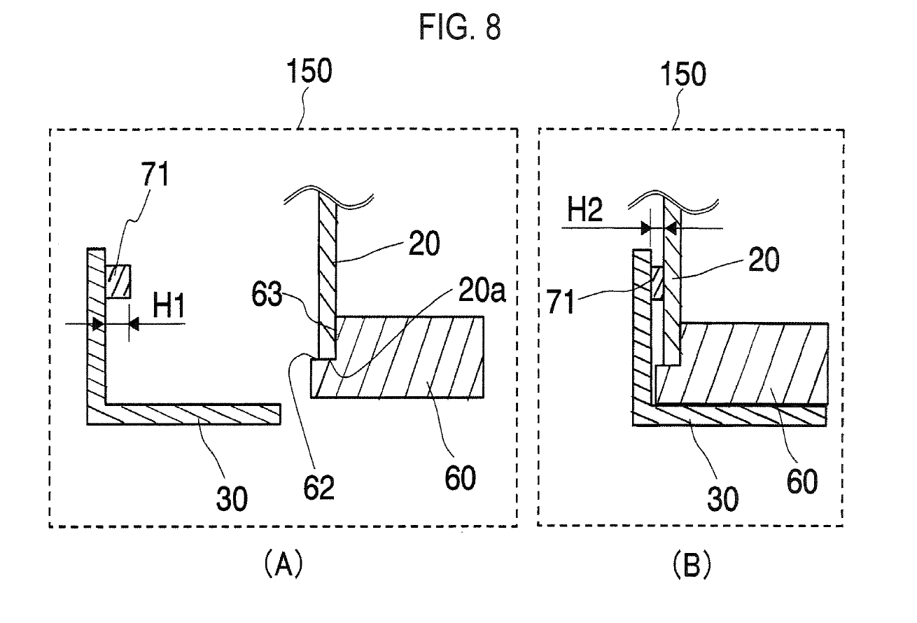

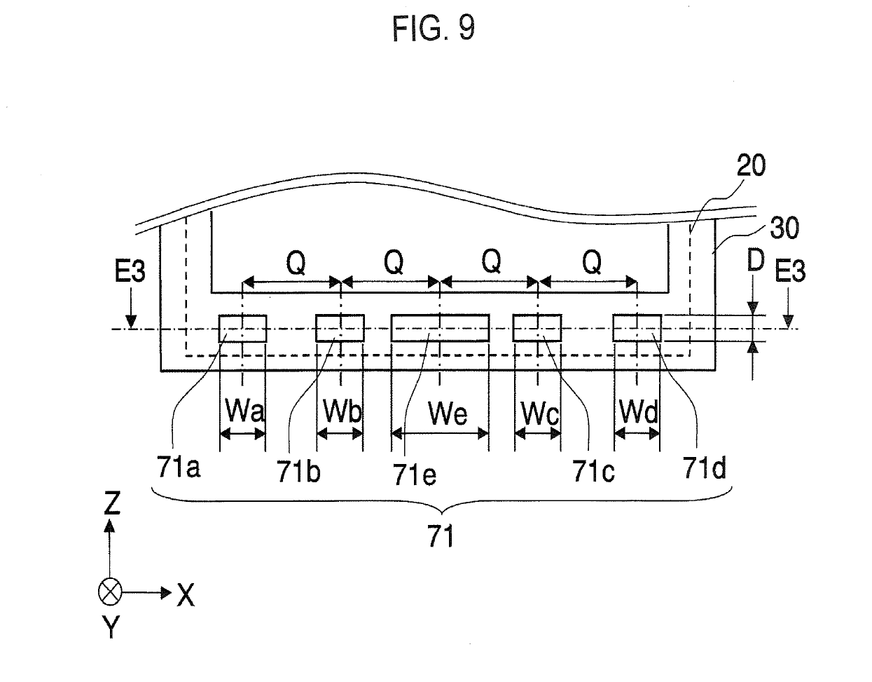

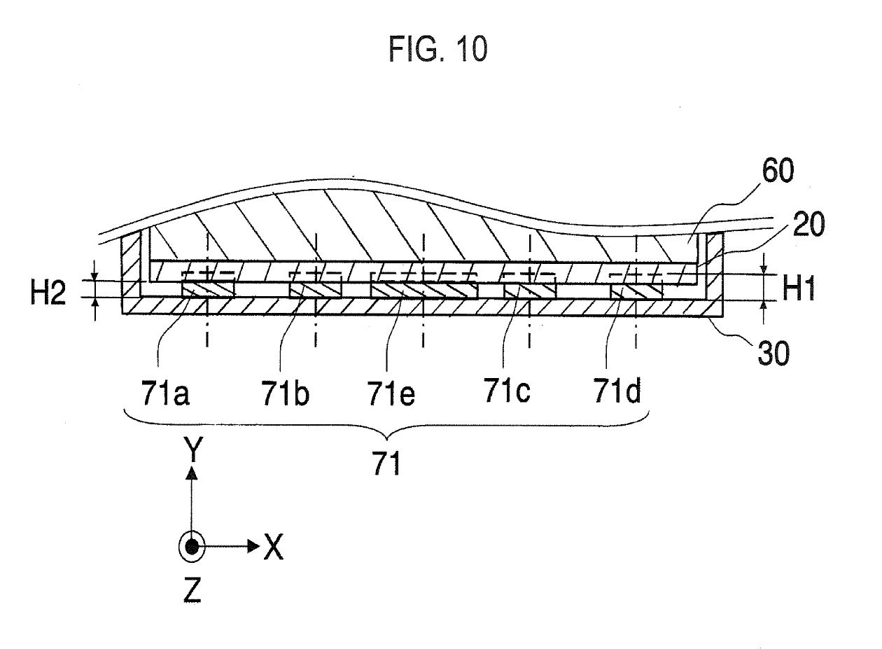

FIG. 8 is a sectional view of a vicinity of the lower end portion 20a of the liquid crystal panel 20. FIG. 9 is a detailed view showing a maim part, i.e., a vicinity of the lower end portion of the liquid crystal panel module 10. FIG. 10 is a partial sectional view taken along a line E3-E3 in FIG. 9. In this regard, components that are the same as those of Embodiment 1 are assigned the same reference numerals, and explanations thereof will be omitted.

In FIG. 8, a receiving surface 62 provided on the lower end portion of the chassis 60 receives the lower end portion 20a of the liquid crystal panel 20. The cushions as the resilient members are affixed to an inner surface of the frame 30 using a double-faced adhesion tape or the like at positions where the cushions 71 face the liquid crystal panel 20. FIG. 8(A) shows a state before the frame 30 is attached to the chassis 60. The cushions 71 have an initial height H1 before being compressed. FIG. 8(B) shows a state after the frame 30 is attached to the chassis 60. The cushions 71 are compressed by the frame 30 and the liquid crystal panel 20, and have a height H2. A liquid crystal panel unit 150 includes the liquid crystal panel 20, the frame 30 and the chassis 60.

In FIG. 9, the cushions 71a, 71b, 71c, 71d and 71e as resilient members are bonded to an inner side of the frame 30 using double-faced adhesion tapes at positions where the cushions 71a, 71b, 71c, 71d and 71e face the liquid crystal panel 20. Widths Wa, Wb, Wc and Wd of the cushions 71a, 71b, 71c and 71d in the X direction are the same. A width We of the cushion 71e in the X direction is greater than the widths Wa, Wb, Wc and Wd of the cushions 71a, 71b, 71c and 71d. The cushions 71a, 71b, 71c, 71d and 71e are arranged at constant pitches Q in the X direction.

When the cushions 71a, 71b, 71c and 71d are compressed from the height H1 to the height H2, the cushions 71a, 71b, 71c and 71d press the liquid crystal panel 20 with pressing forces Pa, Pb, Pc and Pd. A friction coefficient between the cushions 71a, 71b, 71c and 71d and the liquid crystal panel 20 is expressed by μ_{c}. Friction forces between the cushions 71a, 71b, 71c and 71d and the liquid crystal panel 20 are respectively μ_{c}×Pa, μ_{c}×Pb, μ_{c}×Pc and μ_{c}×Pd.

The pressing forces Pa, Pb, Pc and Pd of the cushions 71a, 71b, 71c and 71d are determined by compression amounts and pressing areas of the cushions. The compression amounts of the cushions 71a, 71b, 71c and 71d are the same as each other, and are (H1-H2). Therefore, pressing forces per unit area are the same as each other.

A contact area S of each cushion 71 contacting the liquid crystal panel 20 is determined by a relational expression S=width D×length W. The width D is a length of the cushion 71 in the Z direction. The length W is a length of the cushion 71 in the X direction. Widths of the cushions 71a, 71b, 71c and 71d are the same as each other, and are D. The lengths Wa, Wb, We and Wd are the same as each other. Therefore, the contact areas Sa, Sb, Sc and Sd become the same value. Therefore, the pressing forces Pa, Pb, Pc and Pd become the same value. Further, the friction forces μ_{c}×Pa, μ_{c}×Pb, μ_{c}×Pc and μ_{c}×Pd become the same value.

In this case, as described in Embodiment 1, as the temperature of the liquid crystal panel module 10 rises, dimensional changes of the liquid crystal panel 20 and the frame 30 may occur. The friction forces applied to the liquid crystal panel 20 by the cushions 71a, 71b, 71c and 71d cancel each other and become zero, since the cushions 71a and 71b apply the friction forces to the liquid crystal panel 20 in the +X direction, and the cushions 71c and 71d apply the friction forces to the liquid crystal panel 20 in the −X direction. For this reason, a reference position of the positional displacement of the liquid crystal panel 20 with respect to the frame 30 in the X direction is the center position of the liquid crystal panel 20 in the X direction.

However, there is a variation in the spring coefficient of the cushions 71. There is also a variation in the friction coefficient μ_{c}. Therefore, the friction forces applied to the liquid crystal panel 20 by the cushions 71a, 71b, 71c and 71d do not become zero by canceling each other.

For this reason, for example, it is assumed that the friction forces of the cushions 71a and 71b are at the maximum in a range of the variation. Further, it is assumed that, for example, the friction forces of the cushions 71c and 71d are at the minimum in a range of the variation. However, if the friction force of the cushion 71e is greater than a difference between the friction forces, the frame 30 expands in the X direction with respect to the cushion 71e as a reference position. The cushion 71e is disposed at the center of the liquid crystal panel 20 in the X direction.

The frame 30 is attached to the chassis 60. Therefore, when the frame 30 expands in the X direction with respect to the center of the liquid crystal panel 20 in the X direction, the chassis 60 also expands in the X direction with respect to nearly the center of the liquid crystal panel 20 in the X direction. The circuit boards 40 are attached to the chassis 60. It is optimum that the frame 30 is positioned with respect to the chassis 60 at the position corresponding to the center of the liquid crystal panel 20 in the X direction. In this case, it is ensured that the chassis 60 expands with respect to the center of the liquid crystal panel 20 in the X direction.

In this regard, the friction force applied to the liquid crystal panel 20 by the chassis 60 is considered to be very small. The friction force applied to the liquid crystal panel 20 by the chassis 60 includes a friction force between the lower end portion 20a of the liquid crystal panel 20 and the receiving surface 62 of the chassis 60 and a friction force between the receiving surface 63 and the back surface of the liquid crystal panel 20. The receiving surface 63 is a surface receiving the back surface side of the liquid crystal panel 20.

In the case where the friction force applied by the chassis 60 to the liquid crystal panel 20 is not negligible, a difference is determined between a sum of the friction forces applied to the liquid crystal panel 20 by the +X direction part of the chassis 60 with respect to the center of the liquid crystal panel 20 and a sum of the friction forces applied to the liquid crystal panel 20 by the −X direction part of the chassis 60. It is necessary to add a value of the difference to the above described friction force applied to the liquid crystal panel 20 by the cushions 71, so as to determine a value of the friction force applied to the liquid crystal panel 20 by the cushion 71e.

In this regard, in Embodiment 2, the pressing forces P are varied by varying the dimensions, i.e., the lengths W of the cushions 71. However, the pressing forces P can also be varied by varying the contact areas S of the cushions 71. For this reason, it is also possible to vary the widths D of the cushions 71.

Further, the pressing forces P can be varied by varying the initial heights H of the cushions 71. Further, the pressing forces P can be varied by varying the compression amounts of the cushions 71 by providing concaves and convexes on the inner surface of the frame 30 to which the cushions 71 are attached. Further, the pressing forces P can be varied by using the cushions 71 having different elastic coefficients.

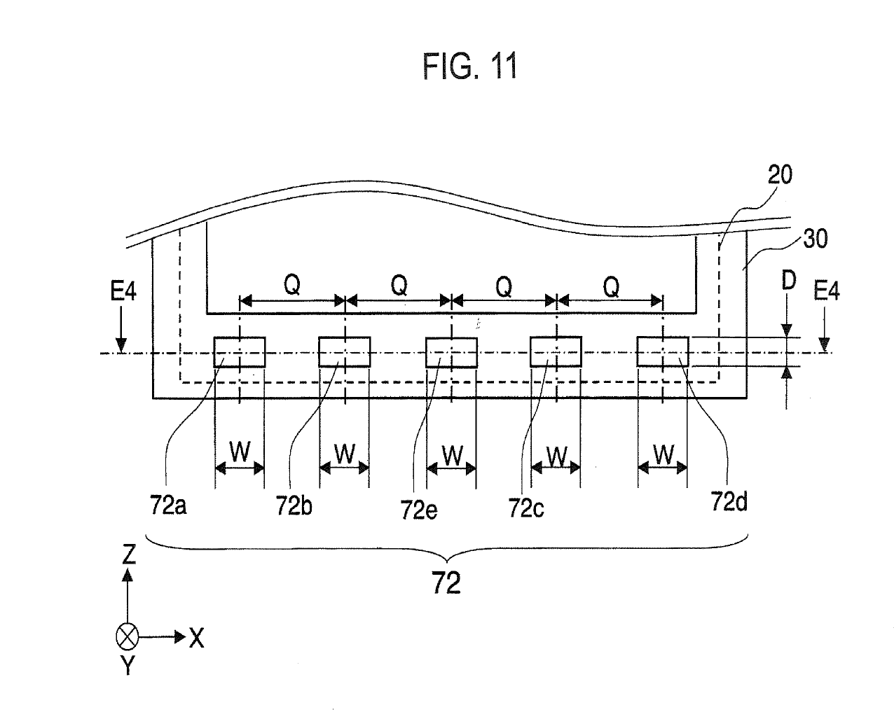

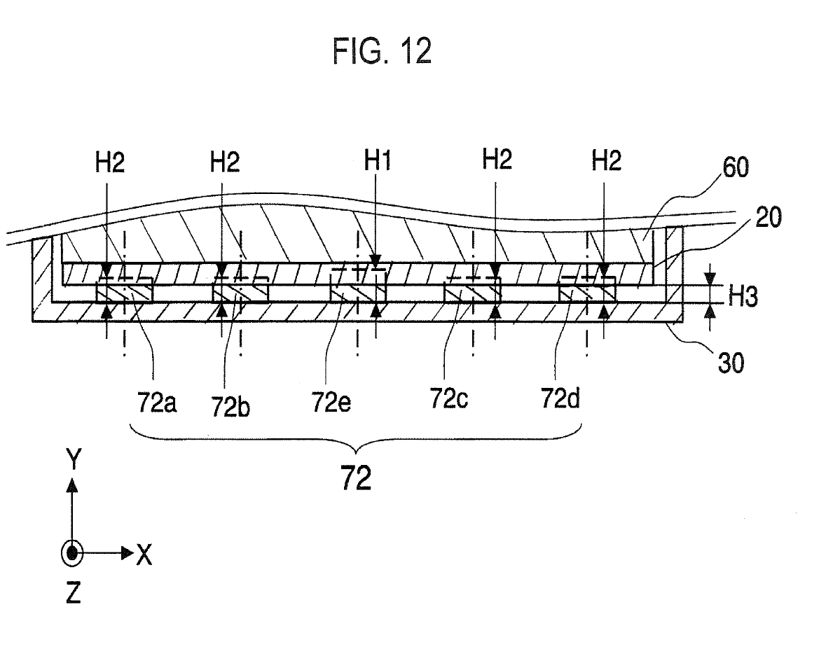

For example, FIGS. 11 and 12 show an example in which the pressing forces with which the cushions 72 press the liquid crystal panel 20 are varied by varying the heights of the cushions 72. FIG. 12 is a partial sectional view taken along a line E4-E4 in FIG. 11. The cushions 72 have the same lengths W, the same widths D and the same elastic coefficients. However, the cushions 72a, 72b, 72c and 72d have the height H2, but the cushion 72e has the height H1. The height H1 is greater than the height H2. The cushions 72a, 72b, 72c, 72d and 72e are compressed to the height H3. This creates a difference among the compression amounts of the cushions 72, so that the cushion 72e has a larger pressing force than the other cushions 72a, 72b, 72c and 72d.

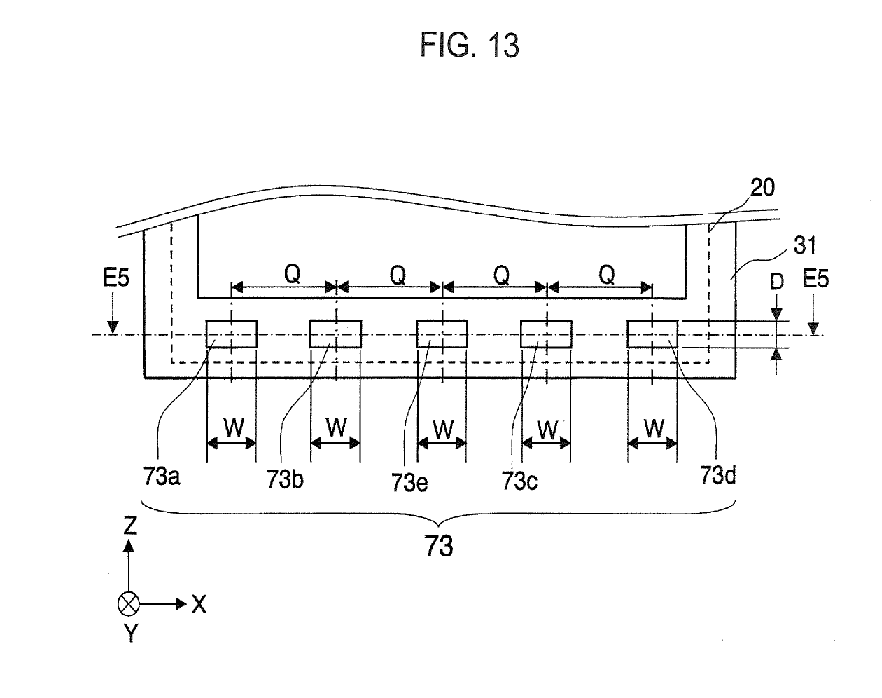

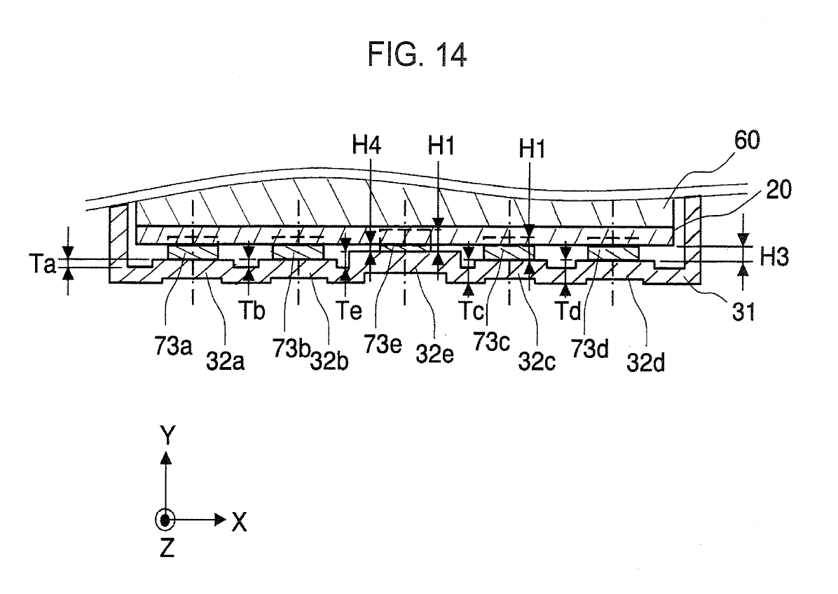

FIGS. 13 and 14 show an example in which an attaching portion of the frame 31 to which the cushions 73 are attached has a convex-shape protruding toward the liquid crystal panel 20. FIG. 14 is a sectional view taken along a line E5-E5 in FIG. 13. The cushions 73 have the same length W, the same width D, the same height H1 and the same elastic coefficient. However, a convex amount Te of a convex portion 32e to which the cushion 73e at the center position of the liquid crystal panel 20 in the X direction is attached is larger than convex amounts Ta, Tb, Tc and Td of convex portions 32a, 32b, 32c and 32d to which the cushions 73a, 73b, 73c and 73d are attached. While the compression amount of the cushion 73e is (H1-H4), the compression amounts of the cushions 72a, 72b, 72c and 72d are (H1-H3). A difference is created among the compression amounts of the cushions 72, so that the cushion 72e has a larger pressing force than other cushions 72a, 72b, 72c and 72d.

In the above described respective embodiments, terms such as “parallel” and “perpendicular” representing positional relationships between components or shapes of components are used in some cases. Further, expressions are used with terms such as “approximately” and “almost” such as approximately parallelepiped, approximately 90 degrees and approximately parallel in some cases. These are used to indicate that ranges in consideration of manufacturing tolerances, assembly variations and the like are included. Therefore, even when “approximately” is not described in the claims, the ranges in consideration of manufacturing tolerances, assembly variations and the like are included. Further, when “approximately” is described in the claims, the ranges in consideration of manufacturing tolerances, assembly variations and the like are included.

### DESCRIPTION OF REFERENCE MARKS

10 . . . liquid crystal panel module, 20 . . . liquid crystal panel, 20a . . . lower end portion, 30, 31 . . . frame, 40 . . . circuit board, 50 . . . flexible board, 60 . . . chassis, 60a, 60b, 60c and 60d . . . receiving surface, 61 . . . resilient member, 71, 72 and 73 . . . cushion, 100 . . . liquid crystal display device, 150 . . . liquid crystal panel unit, 200 . . . backlight unit.

1-10. (canceled)

11. A display panel unit comprising:
a display panel having a terminal at a peripheral portion for supplying image signal, the display panel displaying an image;
a circuit board disposed along a side of the display panel, the side having the terminal;
a flexible board connecting a terminal of the display panel and the circuit board, and transmitting image signal from the circuit board to the display panel, and
a housing that holds the circuit board and the display panel,
wherein the circuit board is disposed along a lower side of the display panel.

12. The display panel unit according to claim 11, wherein the circuit board is disposed along one side of the display panel.

13. The display panel unit according to claim 11, wherein the display panel is fixed to the housing at a center portion of the display panel in a direction of the side of the display panel along which the circuit board is disposed,
wherein the display panel is held so that portions of the display panel except the center portion of the display panel are shiftable due to thermal deformation with respect to the housing in the direction of the side of the display panel along which the circuit board is disposed,
wherein the circuit board is fixed to the housing at a center portion of the circuit board in a direction of the side of the display panel along which the circuit board is disposed, and
wherein the circuit board is held so that portions of the circuit board except the center portion of the circuit board are shiftable due to thermal deformation with respect to the housing in the direction of the side of the display panel along which the circuit board is disposed.

14. The display panel unit according to claim 11, wherein the housing has a receiving surface that receives a lower surface of the display panel, and
wherein the display panel is fixed to the housing in such a manner that a friction force applied to the receiving surface at the center portion in the direction of a side of the display panel is greater than a sum of friction forces applied to the receiving surface at other portions.

15. The display panel unit according to claim 14, wherein the housing has a first resilient member fixed to the housing, and
wherein the receiving surface is the first resilient member.

16. The display panel unit according to claim 11, wherein the display panel unit further comprises a frame body that holds the display panel from a display surface side, and a second resilient member provided on the housing at a position where the second resilient member faces the display surface of the display panel,
wherein the display panel is held by being sandwiched by the housing and the frame body, the frame body is fixed to the housing, and the second resilient member presses the display panel against the housing.

17. A display panel module comprising:
the display panel unit according to claim 11, and
a backlight unit that illuminates the display panel unit.

18. A display device comprising the display panel unit according to claim 11.

19. A display device comprising the display panel module according to claim 17.
